(19) United States
(12) Patent Application Publication
(10) Pub. No.: US 2026/0114128 A1
(43) Pub. Date: Apr. 23, 2026

(54) DISPLAY DEVICE AND METHOD FOR FABRICATION THEREOF

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 19/259,173

(22) Filed: Jul. 3, 2025

(30) Foreign Application Priority Data
Oct. 18, 2024 (KR) 10-2024-0142631

(51) Int. Cl. H10K 59/122; H10H 29/01; H10H 29/37; H10H 29/80; H10K 59/12; H10K 59/80; H10K 71/16; H10K 71/60; H10K 102/00

(52) U.S. Cl. CPC H10K 59/122; H10H 29/012; H10H 29/032; H10H 29/37; H10H 29/8321; H10K 59/1201; H10K 59/80515; H10K 71/16; H10K 71/60; H10K 2102/311; H10K 2102/351

(57) ABSTRACT

A display device includes a substrate including a light emitting area and a non-light emitting area, a via layer including a first portion positioned on the light emitting area of the substrate and a second portion positioned on the non-light emitting area of the substrate, a first light emitting element positioned on the first portion of the via layer and including an anode electrode, a light emitting layer, and a first cathode electrode, and a bank structure positioned on the second portion of the via layer. The first portion of the via layer includes a protruding portion that protrudes further in a direction perpendicular to the substrate than the second portion, the anode electrode is in contact with the protruding portion of the first portion, and the light emitting layer and the first cathode electrode are in contact with the bank structure.

### CROSS-REFERENCE TO RELATED APPLICATION(S)

This application claims priority to and the benefits of Korean Patent Application No. 10-2024-0142631 under 35 U.S.C. 119, filed on Oct. 18, 2024, in the Korean Intellectual Property Office (KIPO), the entire contents of which are incorporated herein by reference.

### BACKGROUND

### 1. Technical Field

The disclosure relates to a display device and a method for fabrication thereof.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions. The display device may be a flat panel display device such as a liquid crystal display device, a field emission display device, or an organic light emitting display device. Among the flat panel display devices, the light emitting display device may include a light emitting element in which each of the pixels of a display panel may emit light by itself, thereby displaying an image without a backlight unit providing the light to the display panel.

### SUMMARY

Aspects of the disclosure provide a display device capable of a high resolution image and a method for fabrication of the display device.

Aspects of the disclosure are to solve a defect in reliability of a display device.

However, aspects of the disclosure are not restricted to those set forth herein. The above and other aspects of the disclosure will become more apparent to one of ordinary skill in the art to which the disclosure pertains by referencing the detailed description of the disclosure given below.

Details of other embodiments are included in the detailed description and drawings.

In an embodiment, a display device may include a substrate including a light emitting area and a non-light emitting area, a via layer including a first portion positioned on the light emitting area of the substrate and a second portion positioned on the non-light emitting area of the substrate, a first light emitting element positioned on the first portion of the via layer and including an anode electrode, a light emitting layer, and a first cathode electrode, and a bank structure positioned on the second portion of the via layer. The first portion of the via layer may include a protruding portion that protrudes further in a direction perpendicular to the substrate than the second portion, the anode electrode may be in contact with the protruding portion of the first portion, and the light emitting layer and the first cathode electrode may be in contact with the bank structure.

In an embodiment, a thickness of the protruding portion of the via layer may be in a range of about 42% to about 70% of a thickness of the bank structure.

In an embodiment, the protruding portion of the via layer may be spaced apart from the bank structure in a direction parallel to the substrate.

In an embodiment, the display device may further include a pixel defining layer positioned on the first portion of the via layer, covering an edge of the anode electrode, and defining an opening. The pixel defining layer may be in contact with the protruding portion of the first portion.

In an embodiment, the anode electrode and the pixel defining layer may be spaced apart from the bank structure in a direction parallel to the substrate.

In an embodiment, the light emitting layer may be in entirely contact with and covers the pixel defining layer and the anode electrode.

In an embodiment, a thickness of the light emitting layer overlapping the opening in the direction perpendicular to the substrate may have a thickness uniformity less than or equal to about 10%.

In an embodiment, in a portion overlapping the non-light emitting area in the direction perpendicular to the substrate, the light emitting layer may be in contact with and cover the protruding portion of the first portion.

In an embodiment, the bank structure may include a first bank layer in contact with the second portion of the via layer, and a second bank layer positioned on the first bank layer and including a tip that protrudes further toward the light emitting area than a side surface of the first bank layer. The side surface of the first bank layer and the tip of the second bank layer may form an undercut.

In an embodiment, the side surface of the first bank layer may include a first portion in contact with the light emitting layer, and a second portion in contact with the first cathode electrode.

In an embodiment, the first bank layer may include a first surface in contact with the second portion of the via layer, and the anode electrode may be positioned higher than the first surface by a thickness of the protruding portion of the via layer in the direction perpendicular to the substrate.

In an embodiment, the display device may further include a second light emitting element spaced apart from the first light emitting element with the bank structure interposed between the first light emitting element and the second light emitting element. The second light emitting element may include a second cathode electrode, the second cathode electrode may be in contact with the first bank layer, and the first cathode electrode and the second cathode electrode may be electrically connected by the first bank layer.

In an embodiment, the display device may further include a first element inorganic layer positioned on the first light emitting element, and a second element inorganic layer positioned on the second light emitting element. The first element inorganic layer and the second element inorganic layer may be in contact with the first bank layer.

In an embodiment, an end of the first element inorganic layer and an end of the second element inorganic layer may be spaced apart from the second bank layer by a cavity interposed between the second bank and the end of the first element inorganic layer and the end of the second element inorganic layer in the direction perpendicular to the substrate.

In an embodiment, in a portion overlapping the non-light emitting area in the direction perpendicular to the substrate, the first element inorganic layer and the second element inorganic layer may be spaced apart from each other in a direction parallel to the substrate.

In an embodiment, a method for fabrication of a display device may include forming an anode electrode on a substrate including a via layer, forming a pixel defining layer on the anode electrode, forming a protruding portion of the via layer by removing a portion of the pixel defining layer and the via layer, forming a bank structure in a portion that does not overlap the protruding portion of the via layer in a direction perpendicular to the substrate, and forming a light emitting layer and a cathode electrode on the anode electrode to overlap the protruding portion of the via layer in the direction perpendicular to the substrate.

In an embodiment, in the forming of the protruding portion of the via layer by removing the portion of the pixel defining layer and the via layer, the portion of the pixel defining layer and the via layer may be simultaneously removed by a dry etching process.

In an embodiment, in the forming of the bank structure in the portion that may do not overlap the protruding portion of the via layer, the bank structure may include a first bank layer and a second bank layer including different materials, an electrical conductivity of the first bank layer may be higher than an electrical conductivity of the second bank layer, and an etching resistance of the second bank layer may be higher than an etching resistance of the first bank layer.

In an embodiment, in the forming of the light emitting layer and the cathode electrode on the anode electrode to overlap the protruding portion of the via layer, the light emitting layer and the cathode electrode may be formed by a deposition process and a photo pattern process without a separate fine metal mask.

In an embodiment, an electronic device may include at least one display device including a substrate including a light emitting area and a non-light emitting area, a display device accommodating portion in which the at least one display device is accommodated, and an optical member enlarging a display image of the at least one display device or converting a light path. The at least one display device may include a via layer including a first portion positioned on the light emitting area of the substrate and a second portion positioned on the non-light emitting area of the substrate, a light emitting element positioned on the first portion of the via layer and including an anode electrode, a light emitting layer, and a cathode electrode, and a bank structure positioned on the second portion of the via layer. The first portion of the via layer may include a protruding portion that protrudes further in a direction perpendicular to the substrate than the second portion, the anode electrode may be in contact with the protruding portion of the first portion, and the light emitting layer and the cathode electrode may be in contact with the bank structure.

The display device and the method for fabrication of the display device according to the embodiments may provide the high resolution image and solve the defect in reliability of the display device.

However, the effects of the embodiments are not restricted to the one set forth herein. The above and other effects of the embodiments will become more apparent to one of ordinary skill in the art to which the embodiments pertain by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating a head mounted electronic device according to an embodiment;

FIG. 2 is an exploded perspective view illustrating an embodiment of the head mounted electronic device of FIG. 1;

FIG. 3 is a perspective view illustrating a head mounted electronic device according to an embodiment;

FIG. 4 is a perspective view illustrating a display device according to an embodiment;

FIG. 5 is a schematic cross-sectional view illustrating the display device according to an embodiment;

FIG. 6 is a plan view illustrating a display layer of the display device according to an embodiment;

FIG. 7 is a plan view illustrating pixels disposed in a display area in FIG. 6;

FIG. 8 is a schematic cross-sectional view illustrating an embodiment of the display layer taken along line X1-X1′ of FIG. 7;

FIG. 9 is a schematic enlarged cross-sectional view of a display element layer in a first light emitting area in FIG. 8;

FIG. 10 is a schematic enlarged cross-sectional view of a display element layer in a non-light emitting area between the first light emitting area and a second light emitting area in FIG. 8;

FIG. 11 is a schematic cross-sectional view illustrating an embodiment of the display element layer taken along line X3-X3′ of FIG. 7;

FIG. 12 is a flowchart illustrating a method for fabrication of the display element layer of FIG. 8;

FIG. 13 is a schematic cross-sectional view illustrating step S100 of FIG. 12;

FIGS. 14 and 15 are schematic cross-sectional views illustrating step S200 of FIG. 12;

FIGS. 16 to 19 are schematic cross-sectional views illustrating step S300 of FIG. 12; and

FIGS. 20 to 23 are schematic cross-sectional views illustrating step S400 of FIG. 12.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Further, the DR1-axis, the DR2-axis, and the DR3-axis are not limited to three axes of a rectangular coordinate system, such as the X, Y, and Z—axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

The term “about” may include variations of, for example, ±20%, ±10%, or ±5%, from the specified numerical value unless otherwise expressly stated. In some contexts, the term may account for rounding, inherent measurement limitations, or standard tolerances recognized in the relevant technical field. When applied to dimensions, concentrations, or other quantifiable parameters, “about” may include minor deviations that would be understood by a person of ordinary skill in the art as insubstantial in the given context. The scope of “about” should be interpreted in view of standard experimental or clinical tolerances applicable to the field of use. A person skilled in the art would recognize that “about” allows for practical deviations that do not materially alter the intended properties of the invention. Similarly, for mechanical dimensions, “about” may include deviations that are within industry-accepted tolerances and do not materially impact the performance of the disclosure.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

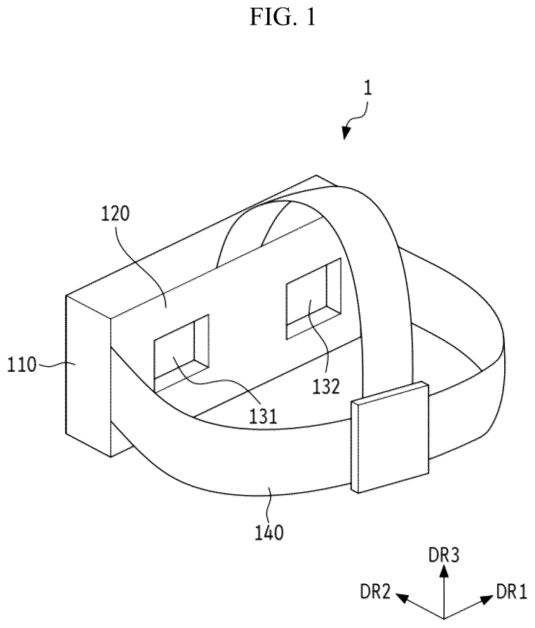

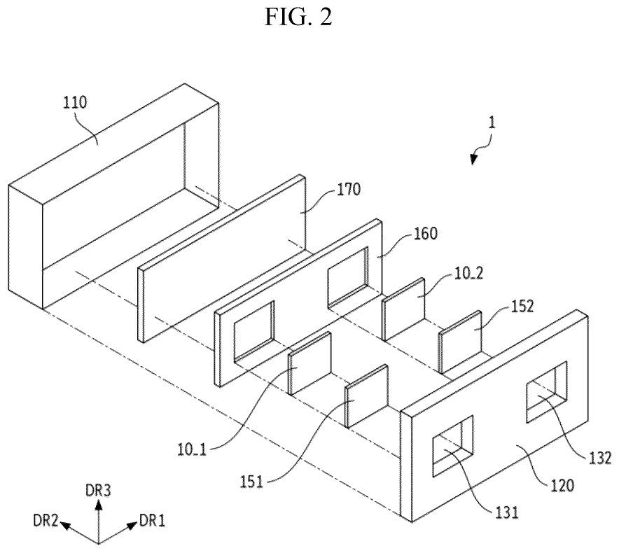

FIG. 1 is a perspective view illustrating a head mounted electronic device according to an embodiment. FIG. 2 is an exploded perspective view illustrating an embodiment of the head mounted electronic device of FIG. 1.

Referring to FIGS. 1 and 2, a head mounted electronic device 1 according to an embodiment may include a display device accommodating portion 110, an accommodating portion cover 120, a first eyepiece 131, a second eyepiece 132, a head mounting band 140, a first display device 10_1, a second display device 10_2, a middle frame 160, a first optical member 151, a second optical member 152, a control circuit board 170, and a connector.

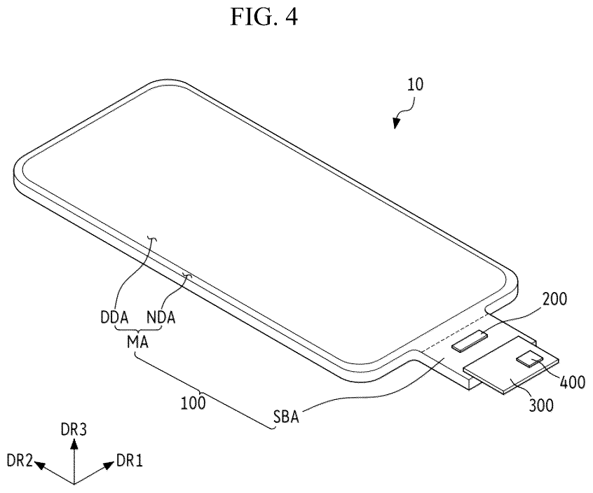

The first display device 10_1 may provide an image to a user's left eye, and the second display device 10_2 may provide an image to a user's right eye. Each of the first display device 10_1 and the second display device 10_2 and a display device 10 described with reference to FIG. 4 may be substantially the same. Accordingly, descriptions of the first display device 10_1 and the second display device 10_2 will be replaced with descriptions with reference to FIG. 4.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and between the second display device 10_2 and the control circuit board 170. The middle frame 160 may support and fix the first display device 10_1, the second display device 10_2, and the control circuit board 170.

The control circuit board 170 may be disposed between the middle frame 160 and the display device accommodating portion 110. The control circuit board 170 may be connected to the first display device 10_1 and the second display device 10_2 through a connector (not illustrated). The control circuit board 170 may convert an image source input from the outside into digital video data, and may transmit the digital video data to the first display device 10_1 and the second display device 10_2 through the connector.

The control circuit board 170 may transmit digital video data corresponding to a left eye image optimized for the user's left eye to the first display device 10_1, and may transmit digital video data corresponding to a right eye image optimized for the user's right eye to the second display device 10_2. In another embodiment, the control circuit board 170 may transmit a same digital video data to the first display device 10_1 and the second display device 10_2.

The display device accommodating portion 110 may accommodate the first display device 10_1, the second display device 10_2, the middle frame 160, the first optical member 151, the second optical member 152, the control circuit board 170, and the connector. The accommodating portion cover 120 may cover an opened surface of the display device accommodating portion 110. The accommodating portion cover 120 may include a first eyepiece 131 where the user's left eye is disposed and a second eyepiece 132 where the user's right eye is disposed. It is illustrated in FIGS. 1 and 2 that the first eyepiece 131 and the second eyepiece 132 are separately disposed, but the disclosure is not limited thereto. The first eyepiece 131 and the second eyepiece 132 may be integral with each other.

The first eyepiece 131 may be aligned with the first display device 10_1 and the first optical member 151, and the second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

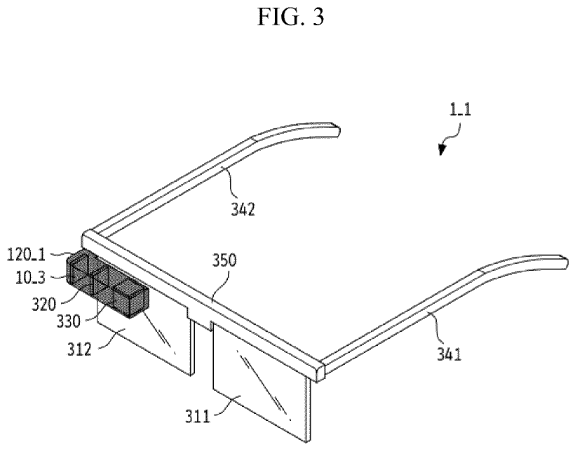

The head mounting band 140 may fix the display device accommodating portion 110 to a user's head so that the first eyepiece 131 and the second eyepiece 132 of the accommodating portion cover 120 are disposed on the user's left and right eyes, respectively. In case that the display device accommodating portion 110 is implemented in a lightweight and small size, the head mounted electronic device 1 may include eyeglass frames as illustrated in FIG. 3 instead of the head mounting band 140.

In an embodiment, the head mounted electronic device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view illustrating a head mounted electronic device according to an embodiment.

Referring to FIG. 3, a head mounted electronic device 1_1 according to an embodiment may be a glasses-type display device in which a display device accommodating portion 120_1 is implemented in a lightweight and small size. The head mounted electronic device 1_1 according to an embodiment may include a display device 10_3, a left eye lens 311, a right eye lens 312, a support frame 350, eyeglass frame legs 341 and 342, an optical member 320, a light path conversion member 330, and a display device accommodating portion 120_1.

The display device 10_3 illustrated in FIG. 3 may be substantially the same as the display device 10 described with reference to FIG. 4.

The display device accommodating portion 120_1 may cover the display device 10_3, the optical member 320, and the light path conversion member 330. As an image displayed on the display device 10_3 is magnified by the optical member 320 and a light path is converted by the light path conversion member 330, the image may be provided to the user's right eye through the right eye lens 312. Accordingly, the user may view an augmented reality image in which a virtual image displayed on the display device 10_3 and a real image viewed through the right eye lens 312 are combined through the right eye.

It is illustrated in FIG. 3 that the display device accommodating portion 120_1 is disposed at a right distal end of the support frame 350, but the disclosure is not limited thereto. For example, the display device accommodating portion 120_1 may be disposed at a left distal end of the support frame 350, and the image of the display device 10_3 may be provided to the user's left eye. In another embodiment, the display device accommodating portions 120_1 may be disposed at both the left and right distal ends of the support frame 350, and the user may view the image displayed on the display device 10_3 through both the user's left and right eyes.

FIG. 4 is a perspective view illustrating a display device according to an embodiment.

Referring to FIG. 4, a display device 10 may be applied to portable electronic devices such as a mobile phone, a smartphone, a tablet personal computer (PC), a mobile communication terminal, an electronic notebook, an electronic book, a portable multimedia player (PMP), navigation, and an ultra mobile PC (UMPC). For example, the display device 10 may be applied to a display unit of a television, a laptop computer, a monitor, a billboard, or the Internet of Things (IOT). For example, the display device 10 may be applied to a wearable device such as a smart watch, a watch phone, a glasses-type display, and a head mounted display (HMD).

The display device 10 may be formed in a planar shape similar to a quadrangle. For example, the display device 10 may have a planar shape similar to a quadrangle having a short side in a first direction DR1 and a long side in a second direction DR2. A corner where the short side in the first direction DR1 and the long side in the second direction DR2 meet may be rounded to have a curvature or may be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA. The main area MA may include a display area DDA including pixels displaying an image, and a non-display area NDA positioned adjacent to the display area DDA.

The display area DDA may emit light from multiple light emitting areas or multiple openings described below. For example, the display panel 100 may include a pixel circuit including switching elements, a pixel defining layer defining the light emitting areas or the openings, and a self-light emitting element. For example, the self-light emitting element may include, but is not limited to, at least one of an organic light emitting diode (LED) including an organic light emitting layer, a quantum dot LED including a quantum dot light emitting layer, an inorganic LED including an inorganic semiconductor, and a micro LED. In the following drawings, it is illustrated that the self-light emitting element is an organic light emitting diode.

The non-display area NDA may be an area outside the display area DDA. The non-display area NDA may be defined as an edge area of the main area MA of the display panel 100.

The sub-area SBA may be an area extending from a side of the main area MA. The sub-area SBA may include a flexible material that may be bendable, foldable, rollable, or the like. For example, in case that the sub-area SBA is bent, the sub-area SBA may overlap the main area MA in a thickness direction (e.g., a third direction DR3). The sub-area SBA may include the display driver 200 and a pad portion connected to the circuit board 300. In another embodiment, the sub-area SBA may be omitted, and the display driver 200 and the pad portion may be positioned in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. For example, the display driver 200 may be positioned in the sub-area SBA, and may overlap the main area MA in the thickness direction by bending of the sub-area SBA. In another embodiment, the display driver 200 may be mounted on the circuit board 300.

The circuit board 300 may be attached onto the pad portion of the display panel 100 using an anisotropic conductive film (ACF). The circuit board 300 may be a flexible film such as a flexible printed circuit board, a printed circuit board, or a chip on film.

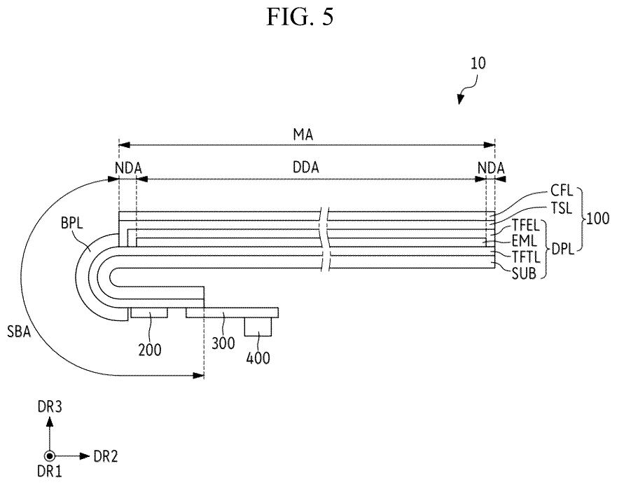

The touch driver 400 may be mounted on the circuit board 300. The touch driver 400 may be connected to a touch sensor layer (TSL in FIG. 5) for sensing and driving a touch of the display device 10.

FIG. 5 is a schematic cross-sectional view illustrating the display device according to an embodiment.

Referring to FIG. 5, the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate or a base member. The substrate SUB may be a flexible substrate that may be bendable, foldable, rollable, or the like. For example, the substrate SUB may include a polymer resin such as polyimide PI, but the disclosure is not limited thereto. In another embodiment, the substrate SUB may include a glass material or a metal material.

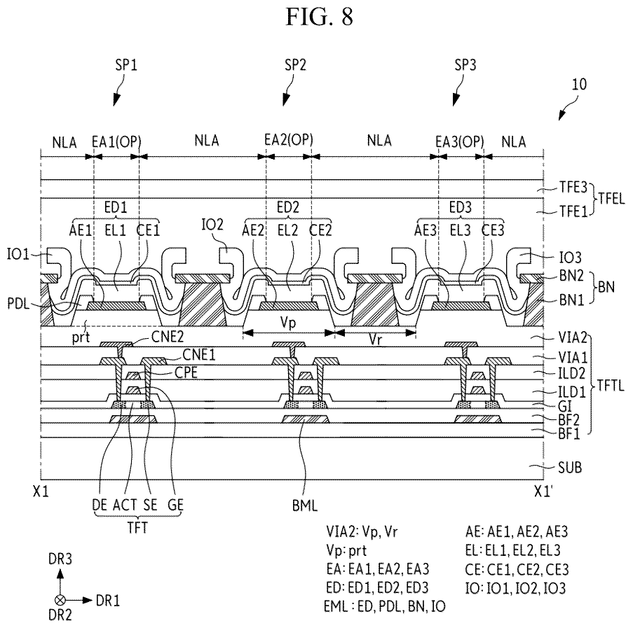

The transistor layer TFTL may be positioned on the substrate SUB. The transistor layer TFTL may be positioned in a portion overlapping the display area DDA, the non-display area NDA, and the sub-area SBA. The transistor layer TFTL may include multiple transistors (“TFT” in FIG. 8).

The display element layer EML may be disposed on the transistor layer TFTL. The display element layer EML may be positioned in a portion overlapping the display area DDA. The display element layer EML may include, but is not limited to, at least one of an organic light emitting diode (LED) including an organic light emitting layer, a quantum dot LED including a quantum dot light emitting layer, an inorganic LED including an inorganic semiconductor, and a micro LED.

The thin film encapsulation layer TFEL may be positioned on the display element layer EML. The thin film encapsulation layer TFEL may be positioned in a portion overlapping the display area DDA and the non-display area NDA. The thin film encapsulation layer TFEL may cover an upper surface and side surfaces of the display element layer EML, and may protect the display element layer EML from oxygen and moisture from the outside. The thin film encapsulation layer TFEL may include at least one inorganic film and at least one organic film for encapsulating the display element layer EML. In some embodiments, the thin film encapsulation layer TFEL may be omitted.

The touch sensor layer TSL may be positioned on the thin film encapsulation layer TFEL. The touch sensor layer TSL may be positioned in a portion overlapping the display area DDA and the non-display area NDA. The touch sensor layer TSL may sense a user's touch in a mutual capacitance method or a self-capacitance method. In some embodiments, the touch sensor layer TSL may be omitted.

The color filter layer CFL may be positioned on the touch sensor layer TSL. The color filter layer CFL may be positioned in a portion overlapping the display area DDA and the non-display area NDA. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is directly disposed on the touch sensor layer TSL, the display device 10 may not require a separate substrate for the color filter layer CFL. Therefore, the display device 10 may have a relatively small thickness. In some embodiments, the color filter layer CFL may be omitted.

As illustrated in FIG. 5, a portion of the display panel 100 in the sub-area SBA may be bendable. In case that a portion of the display panel 100 is bent, the display driver 200, circuit board 300, and the touch driver 400 may overlap the main area MA in the third direction DR3.

In case that a portion of the display panel 100 is bent, a bending protection layer BPL may protect a lower structure positioned to overlap the sub-area SBA from bending stress.

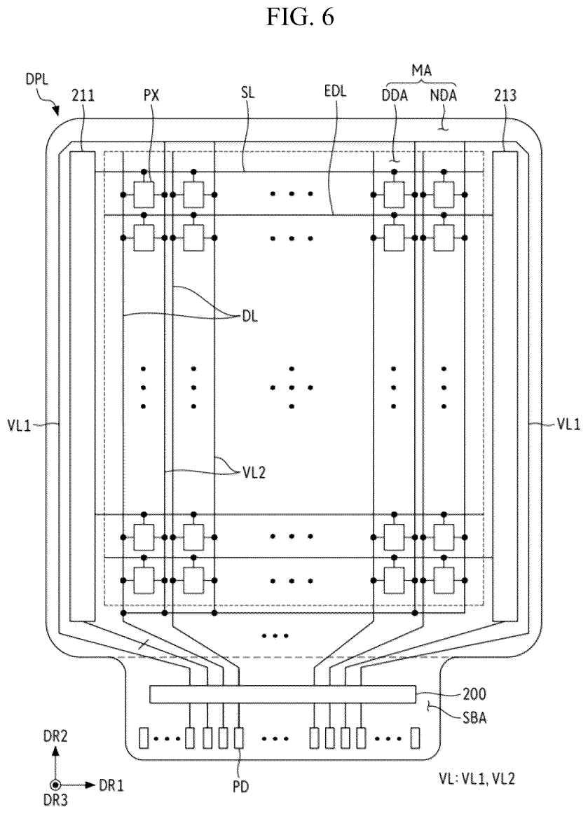

FIG. 6 is a plan view illustrating a display layer of the display device according to an embodiment.

Referring to FIG. 6, the display layer DPL may include multiple pixels PX in a portion overlapping the display area DDA, and multiple power lines VL, multiple scan lines SL, multiple emission control lines EDL, and multiple data lines DL that are connected to the pixels PX.

Each of the scan lines SL may extend in the first direction DR1 and may be spaced apart from each other in the second direction DR2 intersecting the first direction DR1. The scan lines SL may be arranged in the second direction DR2. The scan lines SL may sequentially supply a scan signal to the pixels PX.

Each of the emission control lines EDL may extend in the first direction DR1 and may be spaced apart from each other in the second direction DR2. The emission control lines EDL may be arranged in the second direction DR2. The emission control lines EDL may sequentially supply a light emitting signal to the pixels PX.

The data lines DL may extend in the second direction DR2 and may be spaced apart from each other in the first direction DR1. The data lines DL may be arranged in the first direction DR1. The data lines DL may supply a data voltage to the pixels PX. The data voltage may determine luminance of each of the pixels PX.

The power line VL may include a main power line VL1 and a sub-power line VL2. At least one of a first power voltage (high potential voltage) and a second power voltage (low potential voltage) may be transmitted to the sub-power line VL2 through the main power line VL1 disposed in the non-display area NDA. Hereinafter, the main power line VL1 and the sub-power line VL2 may be collectively referred to as the power line VL.

The non-display area NDA may surround the display area DDA. The non-display area NDA may include a scan driver 211 and the emission control driver 213.

The scan driver 211 may be disposed on the outside of a side of the display area DDA or on a side of the non-display area NDA. The scan driver 211 may include multiple driving transistors that generate gate signals based on a gate control signal.

The emission control driver 213 may be disposed on the outside of another side of the display area DDA or on another side of the non-display area NDA. The emission control driver 213 may include multiple emission control transistors that generate light emitting signals based on an emission control signal.

The display layer DPL according to an embodiment may include a display driver 200 and multiple pad electrodes PD in a portion overlapping the sub-area SBA. The pad electrodes PD may be spaced apart from each other in the first direction DR1, and each pad electrode PD may be connected to each line.

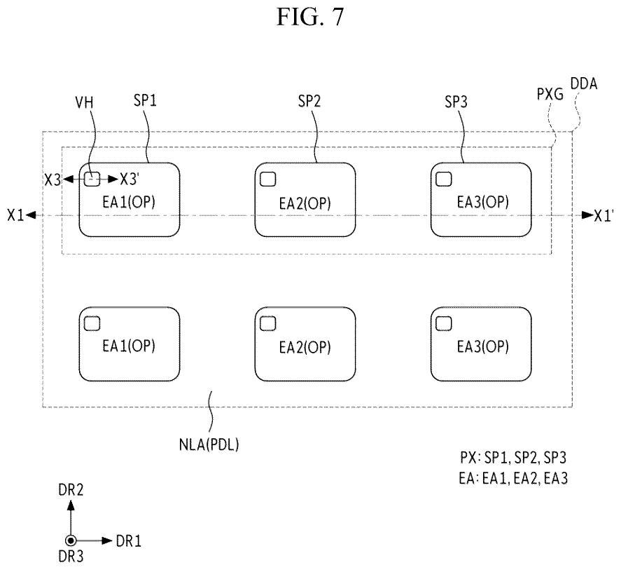

FIG. 7 is a plan view illustrating pixels disposed in a display area in FIG. 6.

Referring to FIG. 7, the display device 10 according to an embodiment may include multiple pixels PX in a portion overlapping the display area DDA. The pixel PX may include a first sub-pixel SP1, a second sub-pixel SP2, and a third sub-pixel SP3. The first sub-pixel SP1, the second sub-pixel SP2, and the third sub-pixel SP3 may be spaced apart from each other.

The pixel PX may emit light, and the pixel PX may include a light emitting area EA. The light emitting areas EA may include a first light emitting area EA1, a second light emitting area EA2, and a third light emitting area EA3 that emit light of different colors. In an embodiment, the first light emitting area EA1 may emit red light of a first color, the second light emitting area EA2 may emit green light of a second color, and the third light emitting area EA3 may emit blue light of a third color, but the disclosure is not limited thereto.

In some embodiments, a first sub-pixel SP1 including at least one first light emitting area EA1, a second sub-pixel SP2 including at least one second light emitting area EA2, and a third sub-pixel SP3 including at least one third light emitting area EA3 that are disposed adjacent to each other may configure one pixel group PXG. The pixel group PXG may be a minimum unit that emits white light. However, the type and/or number of light emitting areas constituting the pixel group PXG may be variously changed according to embodiments.

It is illustrated in the drawing that the size and shape of each of the first to third light emitting areas EA1, EA2, and EA3 are the same, but the disclosure is not limited thereto. The size and shape of each of the first to third light emitting areas EA1, EA2, and EA3 may be freely adjusted according to required characteristics.

In a plan view, a via hole VH may be positioned in a portion overlapping the light emitting area EA. The via hole VH may be a contact hole for electrically connecting an anode electrode (AE in FIG. 8) and a second connection electrode (CNE2 in FIG. 8) described below. Details will be described below.

The non-light emitting area NLA according to an embodiment may be positioned to surround each of the first to third light emitting areas EA1, EA2, and EA3. The non-light emitting area NLA may assist in preventing the light emitted from each of the first to third light emitting areas EA1, EA2, and EA3 from being mixed.

In a plan view, a pixel defining layer PDL may be positioned in a portion overlapping the non-light emitting area NLA. The pixel defining layer PDL may define an opening OP and be positioned to surround the opening OP. In a plan view, the opening OP may be positioned in a portion overlapping the light emitting area EA.

FIG. 8 is a schematic cross-sectional view illustrating an embodiment of the display layer taken along line X1-X1′ of FIG. 7. FIG. 8 schematically illustrates a cross-sectional view of the display layer DPL in a portion overlapping the first sub-pixel SP1, the second sub-pixel SP2, and the third sub-pixel SP3 in FIG. 7. Since the substrate MSUB has already been described, the description thereof will be omitted.

Referring to FIG. 8, a transistor layer TFTL may be positioned on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a first via layer VIA1, a second connection electrode CNE2, and a second via layer VIA2.

The first buffer layer BF1 may be positioned on the substrate SUB. The first buffer layer BF1 may include an inorganic film capable of preventing permeation of air or moisture. For example, the first buffer layer BF1 may include multiple inorganic films alternately stacked each other.

The lower metal layer BML may be positioned on the first buffer layer BF1. The lower metal layer BML may include a conductive metal and may be formed of, for example, a single layer or a multi-layer including at least one of molybdenum (Mo), aluminum (Al), chromium (Cr), gold (Au), titanium (Ti), nickel (Ni), neodymium (Nd), and copper (Cu), and an alloy thereof.

The second buffer layer BF2 may cover the first buffer layer BF1 and the lower metal layer BML. The second buffer layer BF2 may include an inorganic film capable of preventing permeation of air or moisture. For example, the second buffer layer BF2 may include multiple inorganic films alternately stacked each other.

The transistor TFT may be disposed on the second buffer layer BF2, and may constitute a pixel circuit connected to each of the pixels. For example, the transistor TFT may be a driving transistor or a switching transistor of the pixel circuit.

The transistor TFT may include an active layer ACT, a source electrode SE, a drain electrode DE, and a gate electrode GE. The active layer ACT may be positioned on the second buffer layer BF2. The active layer ACT may overlap the gate electrode GE in the third direction DR3 and may be insulated from the gate electrode GE by the gate insulating layer GI. In a portion of the active layer ACT, a material of the active layer ACT may become a conductor to form the source electrode SE and the drain electrode DE.

The gate insulating layer GI may be disposed on the active layer ACT. The gate insulating layer GI may cover the active layer ACT and the second buffer layer BF2, and may insulate the active layer ACT and the gate electrode GE from each other. The gate insulating layer GI may include a contact hole through which the first connection electrode CNE1 penetrates.

The gate electrode GE may be positioned on the gate insulating layer GI. The gate electrode GE may overlap the active layer ACT in the third direction DR3 with the gate insulating layer GI interposed between the gate electrode GE and the active layer ACT. The gate electrode GE may include a conductive metal and may be formed of, for example, a single layer or a multi-layer including at least one of molybdenum (Mo), aluminum (Al), chromium (Cr), gold (Au), titanium (Ti), nickel (Ni), neodymium (Nd), and copper (Cu), and an alloy thereof.

The first insulating layer ILD1 may cover the gate electrode GE and the gate insulating layer GI. The first insulating layer ILD1 may include a contact hole through which the first connection electrode CNE1 penetrates. The contact hole of the first insulating layer ILD1 may be connected to the contact hole of the gate insulating layer GI and a contact hole of the second insulating layer ILD2.

The capacitor electrode CPE may be positioned on the first insulating layer ILD1. The capacitor electrode CPE may overlap the gate electrode GE in the third direction DR3. The capacitor electrode CPE and the gate electrode GE may form a capacitor.

The second insulating layer ILD2 may cover the capacitor electrode CPE and the first insulating layer ILD1. The second insulating layer ILD2 may include a contact hole through which the first connection electrode CNE1 penetrates. The contact hole of the second insulating layer ILD2 may be connected to the contact hole of the first insulating layer ILD1 and the contact hole of the gate insulating layer GI.

The first connection electrode CNE1 may be positioned on the second insulating layer ILD2. The first connection electrode CNE1 may electrically connect the drain electrode DE of the transistor TFT and the second connection electrode CNE2 to each other. The first connection electrode CNE1 may be inserted into the contact holes formed in the first insulating layer ILD1, the second insulating layer ILD2, and the gate insulating layer GI and be in contact with the drain electrode DE of the transistor TFT.

The first via layer VIA1 may cover the first connection electrode CNE1 and the second insulating layer ILD2. The first via layer VIA1 may planarize a lower structure. The first via layer VIA1 may include a contact hole through which the second connection electrode CNE2 penetrates.

The first via layer VIA1 may include an organic insulating material. For example, the first via layer VIA1 may include at least one of an acrylic resin, polyimide, polyamide, benzocyclobutene, and a phenol resin.

The second connection electrode CNE2 may be positioned on the first via layer VIA1. The second connection electrode CNE2 may be inserted into the contact hole formed in the first via layer VIA1 and be in contact with the first connection electrode CNE1. The second connection electrode CNE2 may electrically connect the first connection electrode CNE1 and an anode electrode AE to each other.

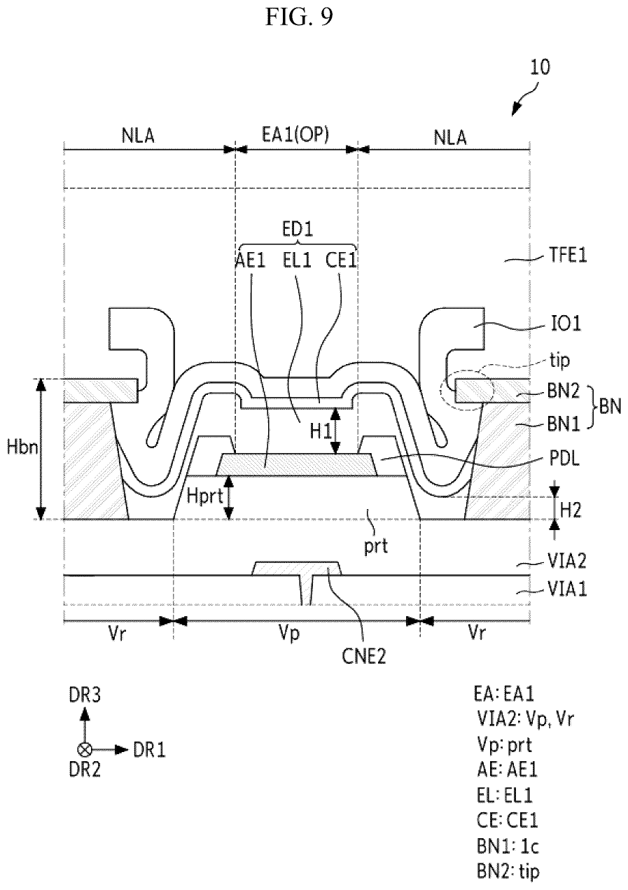

FIG. 9 is a schematic enlarged cross-sectional view of a display element layer in a first light emitting area in FIG. 8.

Referring to FIG. 9 in addition to FIGS. 1 to 8, the second via layer VIA2 may be positioned in a portion overlapping the light emitting area EA and the non-light emitting area NLA. The second via layer VIA2 may entirely cover the second connection electrode CNE2 and the first via layer VIA1.

The second via layer VIA2 may include an organic material. For example, the second via layer VIA2 may include at least one of an acrylic resin, polyimide, polyamide, benzocyclobutene, and a phenol resin.

In an embodiment, the second via layer VIA2 may include a first portion Vp and a second portion Vr.

The first portion Vp may be positioned in a portion overlapping the light emitting area EA, and the second portion Vr may be positioned in a portion overlapping the non-light emitting area NLA. The first portion Vp may include a protruding portion prt that protrudes further in the third direction DR3 than the second portion Vr, and the second portion Vr may not include the protruding portion prt. In other words, the first portion Vp may be a relatively protruding portion of the second via layer VIA2, and the second portion Vr may be a relatively recessed or grooved portion of the second via layer VIA2. In other words, the second via layer VIA2 may include multiple protruding portions prt, and the protruding portions prt may be spaced apart from each other. For example, the second via layer VIA2 may have an uneven structure in which concave and convex portions are repeatedly positioned.

The display element layer EML according to an embodiment may be disposed on the transistor layer TFTL. The display element layer EML may include a light emitting element ED, a pixel defining layer PDL, a bank structure BN, and an element inorganic layer IO.

The light emitting element ED according to an embodiment may be positioned on the second via layer VIA2. The light emitting element ED may include a first light emitting element ED1 disposed in the first light emitting area EA1, a second light emitting element ED2 disposed in the second light emitting area EA2, and a third light emitting element ED3 disposed in the third light emitting area EA3.

The first light emitting element ED1 may include a first anode electrode AE1, a first light emitting layer EL1, and a first cathode electrode CE1, the second light emitting element ED2 may include a second anode electrode AE2, a second light emitting layer EL2, and a second cathode electrode CE2, and the third light emitting element ED3 may include a third anode electrode AE3, a third light emitting layer EL3, and a third cathode electrode CE3.

The first light emitting element ED1, the second light emitting element ED2, and the third light emitting element ED3 may emit light of different colors. For example, the first light emitting element ED1 may emit red light, the second light emitting element ED2 may emit green light, and the third light emitting element ED3 may emit blue light, but the disclosure is not limited thereto.

The first light emitting element ED1, the second light emitting element ED2, and the third light emitting element ED3 may be spaced apart from each other with the bank structure BN interposed between the first light emitting element ED1, the second light emitting element ED2, and the third light emitting element ED3.

The anode electrode AE according to an embodiment may be positioned on the second via layer VIA2. The anode electrode AE may be positioned in a portion overlapping the light emitting area EA and may not overlap the non-light emitting area NLA in the third direction DR3.

The anode electrode AE may be in contact with the protruding portion prt of the second via layer VIA2. In other words, the anode electrode AE may overlap the first portion Vp of the second via layer VIA2 and may not overlap the second portion Vr of the second via layer VIA2 in the third direction DR3.

The anode electrode AE may include a first anode electrode AE1, a second anode electrode AE2, and a third anode electrode AE3. The first anode electrode AE1 may be positioned in a portion overlapping the first light emitting area EA1, the second anode electrode AE2 may be positioned in a portion overlapping the second light emitting area EA2, and the third anode electrode AE3 may be positioned in a portion overlapping the third light emitting area EA3.

The anode electrode AE may have a stacked film structure in which a material layer having a high work function, made of indium tin oxide (ITO), indium zinc oxide (IZO), zinc oxide (ZnO), or indium oxide (In₂O₃) and a reflective material layer made of silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), or a mixture thereof are stacked each other. For example, the anode electrode AE may have a multilayer structure of ITO/Mg, ITO/MgF₂, ITO/Ag, or ITO/Ag/ITO, but the disclosure is not limited thereto.

In an embodiment, the anode electrode AE may not be in contact with the bank structure BN. In other words, the anode electrode AE may be spaced apart from the bank structure BN in the first direction DR1 or the second direction DR2.

The pixel defining layer PDL according to an embodiment may be positioned on the anode electrode AE and the second via layer VIA2. The pixel defining layer PDL may be in contact with the protruding portion prt of the second via layer VIA2. In other words, the pixel defining layer PDL may overlap the first portion Vp of the second via layer VIA2 and may not overlap the second portion Vr of the second via layer VIA2 in the third direction DR3.

In a plan view, the pixel defining layer PDL may define the opening OP and be positioned to surround the opening OP. The pixel defining layer PDL may expose the anode electrode AE in a portion overlapping the opening OP in a plan view. The pixel defining layer PDL may surround an edge of the anode electrode AE in a plan view.

The pixel defining layer PDL may include an inorganic insulating material. For example, the pixel defining layer PDL may include at least one of silicon nitride, silicon oxide, and silicon oxynitride.

In an embodiment, the pixel defining layer PDL may not be in contact with the bank structure BN. In other words, the pixel defining layer PDL may be spaced apart from the bank structure BN in the first direction DR1.

The light emitting layer EL according to an embodiment may be positioned on the anode electrode AE. The light emitting layer EL may be positioned in a portion overlapping the light emitting area EA and the non-light emitting area NLA. The light emitting layer EL may be in contact with the anode electrode AE at a portion overlapping the opening OP in the third direction DR3.

The light emitting layer EL may include a first light emitting layer EL1, a second light emitting layer EL2, and a third light emitting layer EL3. The first light emitting layer EL1 may be positioned in a portion overlapping the first light emitting area EA1, the second light emitting layer EL2 may be positioned in a portion overlapping the second light emitting area EA2, and the third light emitting layer EL3 may be positioned in a portion overlapping the third light emitting area EA3.

The first light emitting layer EL1, the second light emitting layer EL2, and the third light emitting layer EL3 may emit light of different colors. For example, the first light emitting layer EL1 may emit red light, the second light emitting layer EL2 may emit green light, and the third light emitting layer EL3 may emit blue light, but the disclosure is not limited thereto.

The light emitting layer EL may be an organic light emitting layer made of an organic material. The light emitting layer EL may be formed through a deposition process and a photo pattern process without using a separate fine metal mask in the fabricating process. The fabricating process will be described below.

The light emitting layer EL may overlap the protruding portion prt of the second via layer VIA2 in a portion overlapping the light emitting area EA in the third direction DR3, and may be entirely in contact with and cover the first portion Vp and the second portion Vr of the second via layer VIA2 in a portion overlapping the non-light emitting area NLA. The light emitting layer EL may be entirely in contact with and cover the pixel defining layer PDL in a portion overlapping the non-light emitting area NLA. The light emitting layer EL may be in contact with a first bank layer BN1 included in the bank structure BN in a portion overlapping the non-light emitting area NLA.

In an embodiment, a thickness H1 of the light emitting layer EL in the portion overlapping the light emitting area EA may be greater than a thickness H2 of the light emitting layer EL in the portion overlapping the non-light emitting area NLA in the third direction DR3. For example, the thickness H1 of the light emitting layer EL in the portion overlapping the light emitting area EA may be uniform within a process error of 10% or less.

The display device 10 according to an embodiment may solve the problem of light emitting shadow defect caused by uneven thickness of the light emitting layer, because the thickness H1 of the light emitting layer EL is uniformly formed within the aforementioned range in the portion overlapping the light emitting area EA.

The cathode electrode CE according to an embodiment may be positioned on the light emitting layer EL. The cathode electrode CE may be positioned in a portion overlapping the light emitting area EA and the non-light emitting area NLA. The cathode electrode CE may be entirely in contact with the light emitting layer EL.

The cathode electrode CE may include a first cathode electrode CE1, a second cathode electrode CE2, and a third cathode electrode CE3. The first cathode electrode CE1 may be positioned in a portion overlapping the first light emitting area EA1, the second cathode electrode CE2 may be positioned in a portion overlapping the second light emitting area EA2, and the third cathode electrode CE3 may be positioned in a portion overlapping the third light emitting area EA3. The first cathode electrode CE1, the second cathode electrode CE2, and the third cathode electrode CE3 may be spaced apart from each other with the bank structure BN interposed between the first cathode electrode CE1, the second cathode electrode CE2, and the third cathode electrode CE3.

The cathode electrode CE may include a metal layer having a low work function, and may further include a transparent metal oxide layer according to an embodiment. For example, the cathode electrode CE may include a material having a low work function, such as Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg, etc.).

The cathode electrode CE may transmit light generated from the light emitting layer EL by including a transparent conductive material. The cathode electrode CE may be formed through a deposition process and a photo pattern process without using a separate fine metal mask in the fabricating process. The fabricating process will be described below.

The cathode electrode CE may overlap the protruding portion prt of the second via layer VIA2 in a portion overlapping the light emitting area EA in the third direction DR3. The cathode electrode CE may entirely cover the first portion Vp and the second portion Vr of the second via layer VIA2 in a portion overlapping the non-light emitting area NLA. The cathode electrode CE may entirely cover the pixel defining layer PDL in the portion overlapping the non-light emitting area NLA, and may be in contact with the first bank layer BN1 included in the bank structure BN.

The first cathode electrode CE1, the second cathode electrode CE2, and the third cathode electrode CE3, which are spaced apart from each other, may be electrically connected through the first bank layer BN1.

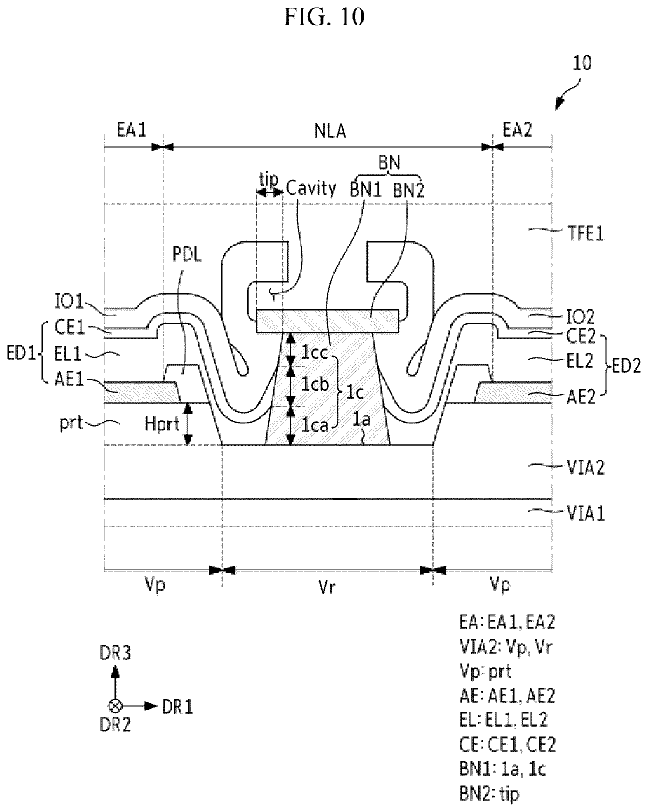

FIG. 10 is a schematic enlarged cross-sectional view of a display element layer in a non-light emitting area between the first light emitting area and a second light emitting area in FIG. 8.

Referring to FIGS. 8 to 10, the bank structure BN according to an embodiment may be positioned in a portion overlapping the non-light emitting area NLA and may not overlap the light emitting area EA in the third direction DR3. The bank structure BN may be in contact with the second portion Vr of the second via layer VIA2. The bank structure BN may not overlap the first portion Vp of the second via layer VIA2 in the third direction DR3.

The bank structure BN may be spaced apart from the protruding portion prt of the second via layer VIA2, the pixel defining layer PDL, and the anode electrode AE in the first direction DR1 or the second direction DR2. In other words, the bank structure BN may not be in contact with the pixel defining layer PDL and the anode electrode AE.

The bank structure BN may include a first bank layer BN1 and a second bank layer BN2. The first bank layer BN1 and the second bank layer BN2 may include different materials and may be sequentially stacked in the third direction DR3.

The first bank layer BN1 according to an embodiment may be positioned on the second via layer VIA2. The first bank layer BN1 may be in contact with the second portion Vr of the second via layer VIA2. The first bank layer BN1 may be spaced apart from the protruding portion prt of the second via layer VIA2, the pixel defining layer PDL, and the anode electrode AE in the first direction DR1 or the second direction DR2.

The first bank layer BN1 may include a metal with high electrical conductivity. For example, the first bank layer BN1 may include aluminum (Al).

In some embodiments, the first bank layer BN1 may include a first surface 1a and a side surface 1c. The first surface 1a of the first bank layer BN1 may be a surface that is in contact with the second portion Vr of the second via layer VIA2, and the side surface 1c may be a surface facing the light emitting area EA or the protruding portion prt of the second via layer VIA2. In the specification, the first surface 1a of the first bank layer BN1 may also be expressed as a first surface 1a of the bank structure BN.

In an embodiment, the anode electrode AE and the pixel defining layer PDL may be positioned on a plane that is higher than the first surface 1a of the first bank layer BN1 in the third direction DR3. In other words, the anode electrode AE and the pixel defining layer PDL may be positioned to be higher than the first surface 1a of the first bank layer BN1 in the third direction DR3 by a thickness Hprt of the protruding portion prt.

The side surface 1c of the first bank layer BN1 may include a first portion 1ca, a second portion 1cb, and a third portion 1cc, depending on the structure in contact with the first bank layer BN1. The first portion 1ca may be a portion that is in contact with the light emitting layer EL, the second portion 1cb may be a portion that is in contact with the cathode electrode CE, and the third portion 1cc may be a portion that is in contact with an element inorganic layer IO described below.

As described above, the light emitting layer EL and the cathode electrode CE according to an embodiment may be formed through a deposition and photo patterning processes during the fabricating process. Accordingly, the light emitting layer EL and the cathode electrode CE may be positioned in contact with the side surface 1c of the first bank layer BN1.

The second bank layer BN2 according to an embodiment may be positioned on the first bank layer BN1. The second bank layer BN2 may overlap the second portion Vr of the second via layer VIA2 and may not overlap the first portion Vp of the second via layer VIA2 in the third direction DR3. The second bank layer BN2 may be spaced apart from the protruding portion prt of the second via layer VIA2, the pixel defining layer PDL, and the anode electrode AE in the first direction DR1 or the second direction DR2.

The second bank layer BN2 may include a conductive metal having etching resistance. For example, the second bank layer BN2 may include titanium (Ti).

The second bank layer 163 may have tips that protrude further on sides toward the light emitting area EA than the side surface 1c of the first bank layer BN1. The tip of the second bank layer BN2 and the side surface 1c of the first bank layer BN1 may form an undercut. In other words, the bank structure BN may have an overhang structure.

The tip of the second bank layer BN2 may be formed during the fabricating process of the bank structure BN as the first bank layer BN1 and the second bank layer BN2 include different etching ratios. The fabricating process will be described below.

In an embodiment, the thickness Hprt of the protruding portion prt of the second via layer VIA2 may be in a range of about 42% to about 70% of a thickness Hbn of the bank structure BN. For example, in case that the thickness Hbn of the bank structure BN is about 7000 Angstroms, the thickness Hbn of the bank structure BN may be in a range of about 3000 Angstroms to about 4900 Angstroms.

In general, the high resolution display device 10 may be formed so that the gap between the first to third light emitting elements ED1, ED2, and ED3 is narrower than the gap of a non-high resolution product. This may mean that the gap between the bank structures BN adjacent to each other with the light emitting element ED interposed between the bank structures BN in the first direction DR1 or the second direction DR2 becomes narrower.

For example, in case that the gap between the bank structures BN adjacent to each other with the light emitting element ED interposed between the bank structures BN is formed to be narrow within a certain range of width (e.g., 3 microns) or less, a thickness H2 of the light emitting layer EL overlapping the tip of the second bank layer BN2 or overlapping the periphery of the tip in the third direction DR3 may have a deviation of more than 10% from the thickness H1 of the light emitting layer EL of a normally deposited portion. For example, in case that a thickness deviation of the light emitting layer EL is greater than 10% in the portion overlapping the light emitting area EA, this may cause a defect in light emitting reliability (e.g., light emitting shadow defect).

Accordingly, the display device 10 according to an embodiment may uniformly form the thickness H1 of the light emitting layer EL positioned in the portion overlapping the light emitting area EA within the range of 10% or less, by forming the second via layer VIA2 to include the protruding portion prt and forming the anode electrode AE on the protruding portion prt of the second via layer VIA2.

In other words, the display device 10 according to an embodiment may be formed so that the light emitting layer EL overlapping the tip of the second bank layer BN2 or overlapping the periphery of the tip in the third direction DR3 does not emit light, by forming the second via layer VIA2 to include the protruding portion prt and forming the anode electrode AE on the protruding portion prt of the second via layer VIA2.

Therefore, the display device 10 may solve the defect in light emitting reliability (e.g., light emitting shadow defect).

The display device 10 according to an embodiment may assist in stably contacting the cathode electrode CE with the first bank layer BN1, by forming the second via layer VIA2 to include the protruding portion prt and forming the bank structure BN on the second portion Vr of the second via layer VIA2, which is a relatively recessed portion. Therefore, the display device 10 may have stable cathode electrical contact characteristics.

The element inorganic layer IO according to an embodiment may be positioned on the light emitting element ED. The element inorganic layer IO may completely cover the light emitting element ED and prevent oxygen or moisture from permeating into the light emitting element ED.

The element inorganic layer IO may include an inorganic insulating material. For example, the element inorganic layer IO may include at least one of silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be disposed on the first light emitting element ED1 in the first light emitting area EA1, the second element inorganic layer IO2 may be disposed on the second light emitting element ED2 in the second light emitting area EA2, and the third element inorganic layer IO3 may be disposed on the third light emitting element ED3 in the third light emitting area EA3. The first element inorganic layer IO1, the second element inorganic layer IO2, and the third element inorganic layer IO3 may be spaced apart from each other in the first direction DR1 in a portion overlapping the non-light emitting area NLA.

An end of the element inorganic layer IO may be spaced apart from the bank structure BN in the third direction DR3 in the portion overlapping the non-light emitting area NLA. For example, an end of the element inorganic layer IO may be spaced from the second bank layer BN2 in the third direction DR3 with a cavity interposed between the end of the element inorganic layer IO and the second bank layer BN2 in the portion overlapping the non-light emitting area NLA.

In the drawing, the first element inorganic layer IO1, the second element inorganic layer IO2, and the third element inorganic layer IO3 appear to be formed on a same layer, but in the fabricating process of the display device 10, the first element inorganic layer IO1 may be formed after the first light emitting element ED1 is formed, the second element inorganic layer IO2 may be formed after the second light emitting element ED2 is formed, and the third element inorganic layer IO3 may be formed after the third light emitting element ED3 is formed. The fabricating process will be described below.

The thin film encapsulation layer TFEL according to an embodiment may be positioned on the display element layer EML. The thin film encapsulation layer TFEL may include an organic encapsulation layer TFE1 and an inorganic encapsulation layer TFE3.

The organic encapsulation layer TFE1 according to an embodiment may be positioned on the element inorganic layer IO. For example, the organic encapsulation layer TFE1 may be entirely in contact with and cover the first element inorganic layer IO1, the second element inorganic layer IO2, and the third element inorganic layer IO3.

The organic encapsulation layer TFE1 may planarize the steps formed according to a profile of the lower structure. Accordingly, the organic encapsulation layer TFE1 may fill the cavity formed between the bank structure BN and an end of the element inorganic layer IO.

The organic encapsulation layer TFE1 may include a polymer-based material. For example, the organic encapsulation layer TFE1 may include at least one of an acrylic resin, a silicone resin, an epoxy resin, a silicone acrylic resin, polyimide, and polyethylene.

The inorganic encapsulation layer TFE3 according to an embodiment may be positioned on the organic encapsulation layer TFE1. The inorganic encapsulation layer TFE3 may protect the lower structure from permeation of moisture and oxygen. In some embodiments, the inorganic encapsulation layer TFE3 may be omitted.

The inorganic encapsulation layer TFE3 may include an inorganic insulating material. For example, the inorganic encapsulation layer TFE3 may include at least one of silicon nitride, silicon oxide, and silicon oxynitride.

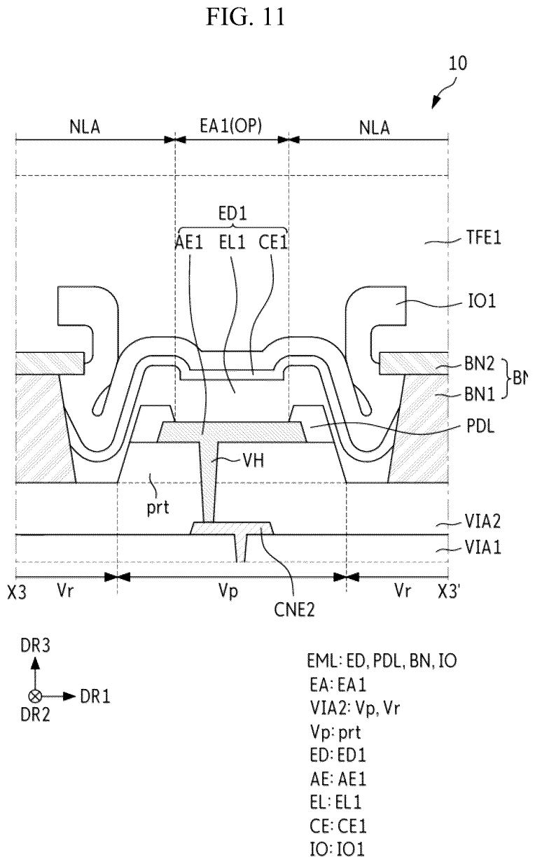

FIG. 11 is a schematic cross-sectional view illustrating an embodiment of the display element layer taken along line X3-X3′ of FIG. 7. FIG. 11 schematically illustrates a display element layer EML overlapping a via hole VH, and the display element layer EML may include a light emitting element ED, a pixel defining layer PDL, a bank structure BN, and an element inorganic layer IO. Hereinafter, differences in the display element layer EML overlapping the via hole VH will be described.

Referring to FIG. 11 in addition to FIGS. 1 to 10, the second connection electrode CNE2 may be positioned in a portion overlapping the first portion Vp of the second via layer VIA2 in the third direction DR3. The via hole VH may not overlap the second portion Vr of the second via layer VIA2 in the third direction DR3.

The via hole VH according to an embodiment may penetrate through the first portion Vp of the second via layer VIA2. In other words, the via hole VH may be formed by penetrating through the protruding portion prt of the second via layer VIA2. In other words, the via hole VH may be surrounded by the protruding portion prt of the second via layer VIA2.

The anode electrode AE may fill the via hole VH. The anode electrode AE may be electrically connected to the second connection electrode CNE2 through the via hole VH.

The light emitting layer EL, the cathode electrode CE, and the element inorganic layer IO included in the light emitting element ED according to an embodiment may overlap the via hole VH in the third direction DR3. The bank structure BN according to an embodiment may be spaced apart from the via hole VH in the first direction DR1. Other redundant descriptions will be omitted.

Hereinafter, a method for fabrication of the display element layer EML included in the display device 10 of FIG. 8 will be described.

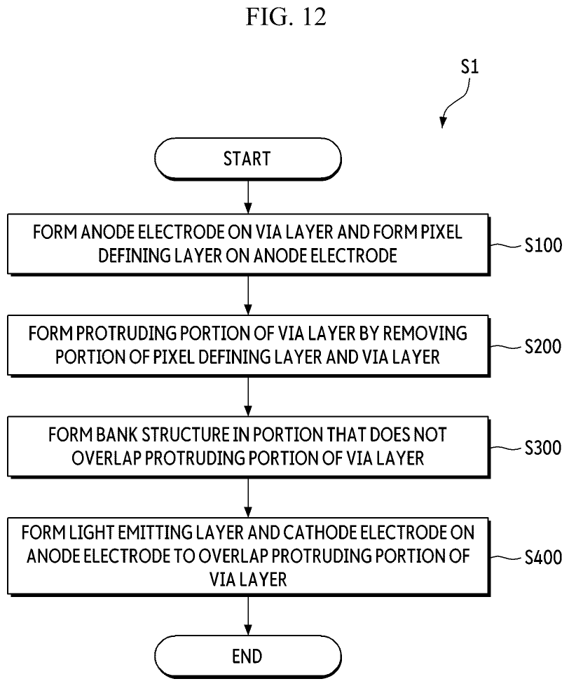

FIG. 12 is a flowchart illustrating a method for fabrication of the display element layer of FIG. 8.

Referring to FIG. 12, a method S1 for fabrication of the display device 10 according to an embodiment may include a step (S100) of forming an anode electrode on a via layer and forming a pixel defining layer on the anode electrode, a step (S200) of forming a protruding portion of the via layer by removing a portion of the pixel defining layer and the via layer, a step (S300) of forming a bank structure in a portion that does not overlap the protruding portion of the via layer, and a step (S400) of forming a light emitting layer and a cathode electrode on the anode electrode to overlap the protruding portion of the via layer.

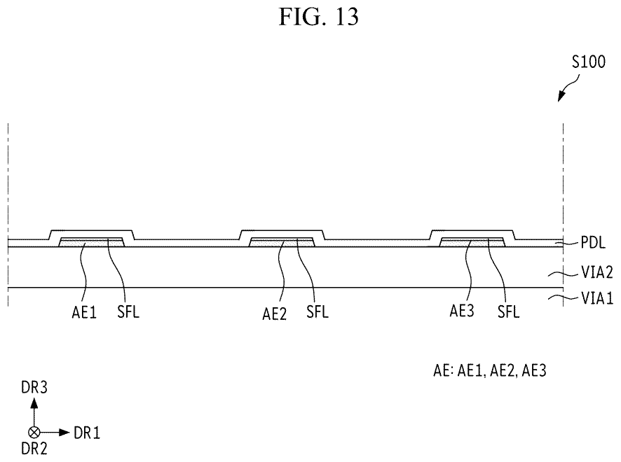

FIG. 13 is a schematic cross-sectional view illustrating step S100 of FIG. 12. The step (S100) of forming an anode electrode on a via layer and forming a pixel defining layer on the anode electrode is described with reference to FIG. 13.

First, multiple anode electrodes AE may be formed on a second via layer VIA2 positioned on a first via layer VIA1. The anode electrode AE may include a first anode electrode AE1, a second anode electrode AE2, and a third anode electrode AE3 that are spaced apart from each other.

A sacrificial layer SFL may be formed on each of the first anode electrode AE1, the second anode electrode AE2, and the third anode electrode AE3. The sacrificial layer SFL may protect the anode electrode AE during a subsequent etching process.

The sacrificial layer SFL may include a transparent oxide electrode TCO, such as indium-tin-oxide (ITO), indium-zinc-oxide (IZO), zinc oxide (ZnO), or indium oxide (In₂O₃).

A pixel defining layer PDL may be formed on the anode electrode AE and the sacrificial layer SFL. In the process, the pixel defining layer PDL may entirely cover the anode electrode AE and the sacrificial layer SFL.

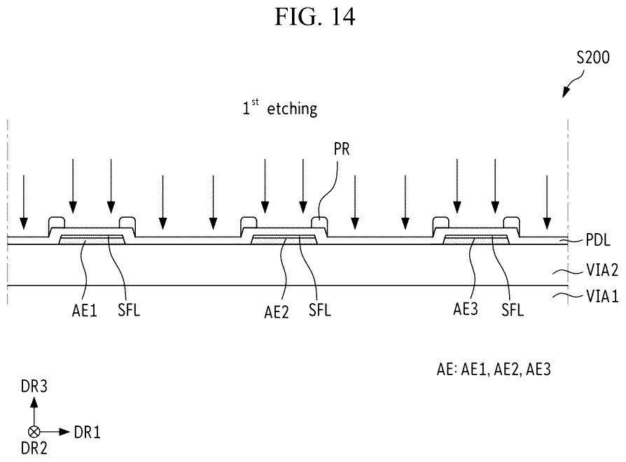

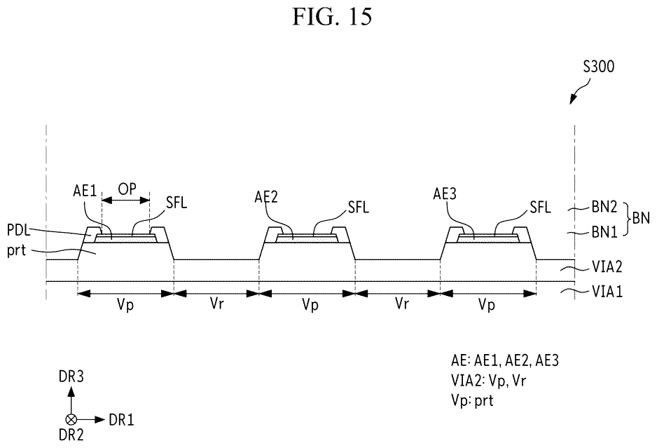

FIGS. 14 and 15 are schematic cross-sectional views illustrating step S200 of FIG. 12.

The step (S200) of forming a protruding portion of the via layer by removing a portion of the pixel defining layer and the via layer is described with reference to FIGS. 14 and 15.

First, multiple photoresists PR may be formed on the pixel defining layer PDL. The photoresists PR may cover an edge of the anode electrode AE and may be spaced apart from each other. A first etching process may be performed using the photoresists PR as masks. For example, the first etching process may be a dry etching process.

In the process, portions of the pixel defining layer PDL and the second via layer VIA2 that do not overlap the photoresists PR in the third direction DR3 may be simultaneously removed.

In the process, the pixel defining layer PDL may define an opening OP in a portion overlapping the anode electrode AE in the third direction DR3, and may expose the sacrificial layer SFL in a portion overlapping the opening OP in the third direction DR3.

In the process, the second via layer VIA2 may include a first portion Vp and a second portion Vr having different shapes. For example, the first portion Vp may be a portion that overlaps the anode electrode AE in the third direction DR3 and may include a protruding portion prt. The second portion Vr may be a portion that does not overlap the anode electrode AE in the third direction DR3 and may not include the protruding portion prt. In other words, the first portion Vp may be a portion that is relatively more protruding in the third direction DR3 than the second portion Vr, and the second portion Vr may be a portion that is relatively more recessed in a direction toward another side in the third direction DR3 than the first portion Vp. The first portion Vp and the second portion Vr of the second via layer VIA2 may be arranged in a repetitive and intersecting manner. The redundant descriptions will be omitted.

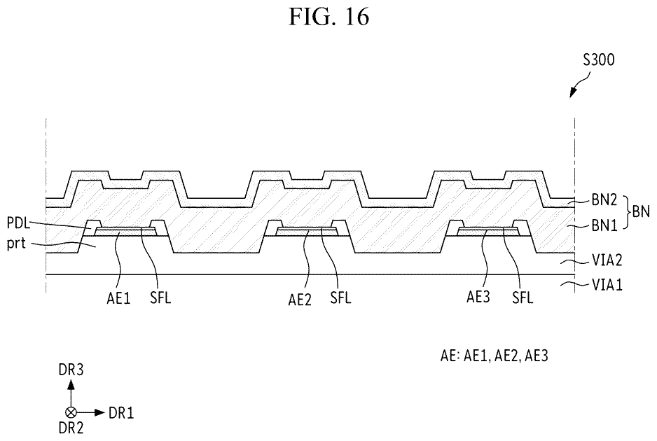

FIGS. 16 to 19 are schematic cross-sectional views illustrating step S300 of FIG. 12.

A step (S300) of forming a bank structure in a portion that does not overlap the protruding portion of the via layer will be described with reference to FIGS. 16 to 19.

First, as illustrated in FIG. 16, a bank structure BN may be formed on the second via layer VIA2 and the pixel defining layer PDL. The bank structure BN may be formed on the front surface and completely cover the second via layer VIA2, the pixel defining layer PDL, and the sacrificial layer SFL.

The bank structure BN may include a first bank layer BN1 and a second bank layer BN2 sequentially stacked in the third direction DR3. The first bank layer BN1 and the second bank layer BN2 may be sequentially stacked and may include different materials. For example, the second bank layer BN2 may include a metal material having greater etching resistance than the first bank layer BN1, and the first bank layer BN1 may include a metal material having higher electrical conductivity than the second bank layer BN2.

In the process, the first bank layer BN1 may be in contact with and cover the second via layer VIA2, the pixel defining layer PDL, and the sacrificial layer SFL, and the second bank layer BN2 may entirely cover the first bank layer BN1.

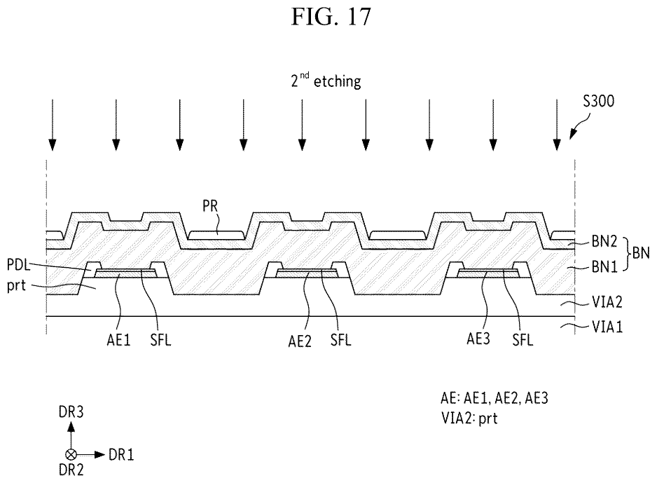

Referring to FIG. 17, multiple photoresists PR may be formed on the second bank layer BN2. The photoresists PR may be formed so as not to overlap the protruding portion prt of the second via layer VIA2 in the third direction DR3.

A second etching process may be performed using the photoresists PR as masks. For example, in the second etching process, a dry etching process and a wet etching process may be sequentially performed.

First, a dry etching process may be performed during the second etching process.

For example, a dry etching process may be performed through a reactive ion etching (RIE) process using reactive gases such as CHF₃, CH₃F, CH₂F₂, CHF₆, CF₄, C₂F₆, and C₃F₆, and sputtering gases such as Ar, and O₂/Ar. An inductively coupled plasma (ICP) source or a capacitively coupled plasma (CCP) source may be used as a plasma source.

In the process, the bank structure BN that does not overlap the photoresists PR in the third direction DR3 may be entirely removed, and as a result, the sacrificial layer SFL may be exposed again in the portion overlapping the opening OP in the third direction DR3. In other words, in the process, the bank structure BN overlapping the protruding portion prt of the second via layer VIA2 in the third direction DR3 may be entirely removed, and the sacrificial layer SFL may be exposed again in the portion overlapping the protruding portion prt of the second via layer VIA2 in the third direction DR3.

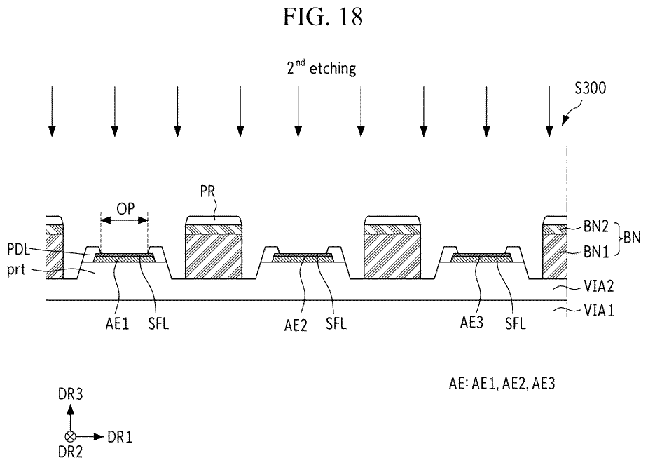

As illustrated in FIG. 18, in the process, the first bank layer BN1 and the second bank layer BN2 positioned to overlap the photoresists PR in the third direction DR3 may be isotropically removed. For example, a side surface of the first bank layer BN1 and a side surface of the second bank layer BN2 positioned to overlap the photoresists PR in the third direction DR3 may be positioned on a same line.

A wet etching process may be performed during the second etching process.

For example, the wet etching process may be performed using a liquid chemical solution such as a hydrofluoric acid solution, a nitric acid solution, a tetramethylammonium hydroxide solution, and a potassium hydroxide solution.

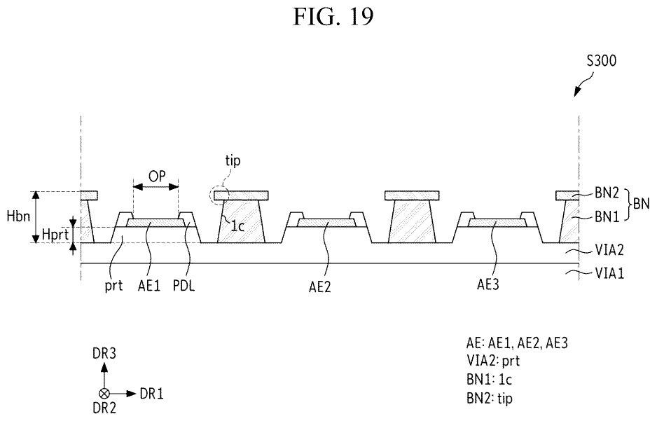

As illustrated in FIG. 19, in the process, the sacrificial layer SFL positioned on the anode electrode AE which is positioned so as not to overlap the photoresists PR may be entirely removed, and the anode electrode AE may be exposed in the portion overlapping the opening OP in the third direction DR3.

In the process, the first bank layer BN1 and the second bank layer BN2 including different metal materials may have different etching selectivities. For example, for a same wet etching solution, the first bank layer BN1 may have a higher etching rate than the second bank layer BN2. Accordingly, the second bank layer BN2 may include a tip that protrudes further in the first direction DR1 or the second direction DR2 than the side surface 1c of the first bank layer BN1. The tip of the second bank layer BN2 may be positioned toward the protruding portion prt of the second via layer VIA2.

In the process, a thickness Hprt of the protruding portion prt of the second via layer VIA2 may be in a range of about 42% to about 70% of a thickness Hbn of the bank structure BN. The redundant descriptions will be omitted.

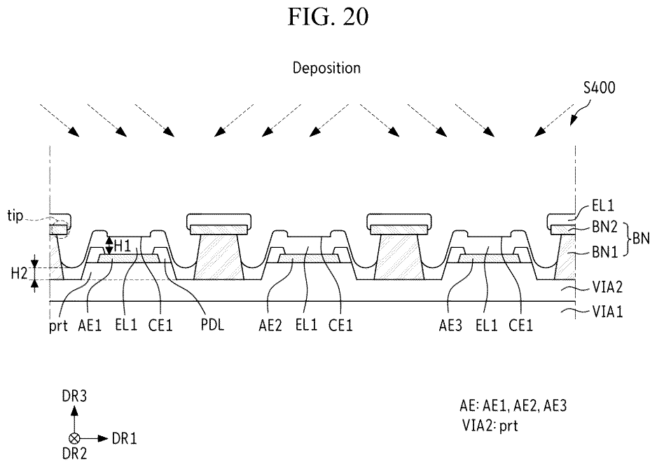

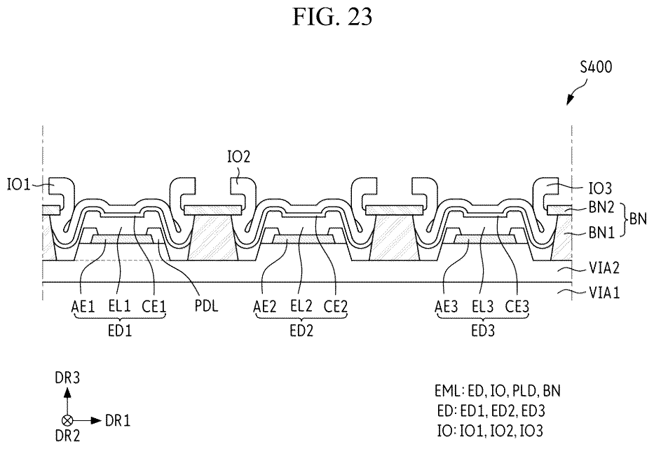

FIGS. 20 to 23 are schematic cross-sectional views illustrating step S400 of FIG. 12.

A step (S400) of forming a light emitting layer and a cathode electrode on the anode electrode to overlap the protruding portion of the via layer will be described with reference to FIGS. 20 to 23.

As illustrated in FIG. 20, a first light emitting layer EL1 may be formed on the first anode electrode AE1. The process of forming the first light emitting layer EL1 may be performed through a deposition process without using a separate fine metal mask.

In an embodiment, the process of forming the first light emitting layer EL1 may be performed while being inclined at a first angle from an upper surface of the anode electrode AE. The first angle described above may be a deposition incidence angle. For example, the first angle may be in a range of about 45 degrees to about 50 degrees. Accordingly, the material forming the first light emitting layer EL1 may be formed on the side surface of the first bank layer BN1 and the side surface of the protruding portion prt of the second via layer VIA2, in addition to the upper surface of the anode electrode AE and the bank structure BN.

However, the material forming the first light emitting layer EL1 formed on each of the first anode electrode AE1, the second anode electrode AE2, the third anode electrode AE3, and the bank structure BN may be spaced apart from each other without being connected to each other, as the second bank layer BN2 includes the tip.

In the process, a thickness H1 of the first light emitting layer EL1 formed on the anode electrode AE and a thickness H2 of the first light emitting layer EL1 formed in a portion overlapping the tip of the second bank layer BN2 may be different from each other. For example, the thickness H1 of the first light emitting layer EL1 formed on the anode electrode AE may be greater than the thickness H2 of the first light emitting layer EL1 formed in the portion overlapping the tip of the second bank layer BN2 in the third direction DR3.

In an embodiment, the thickness H1 of the first light emitting layer EL1 formed on the anode electrode AE may have high thickness uniformity of 10% or less within a process error, but the thickness H2 of the first light emitting layer EL1 formed in a portion overlapping the tip of the second bank layer BN2 and a periphery of the tip of the second bank layer BN2 may have non-uniform thickness that exceeds the process error range.

This may be caused by a decrease in deposition efficiency in the portion overlapping the tip of the second bank layer BN2 as the deposition process of forming the first light emitting layer EL1 is performed with a deposition incidence angle of the first angle. In other words, a portion of the material forming the first light emitting layer EL1 may be locked by the tip of the second bank layer BN2.

The display device 10 according to an embodiment may form a portion of the first light emitting layer EL1 having high thickness uniformity in a light emitting area, and a portion of the first light emitting layer EL1 positioned in the portion overlapping the tip of the second bank layer BN2 in a non-light-emitting area, by forming the anode electrode AE on the protruding portion prt of the second via layer VIA2. Other redundant descriptions will be omitted.

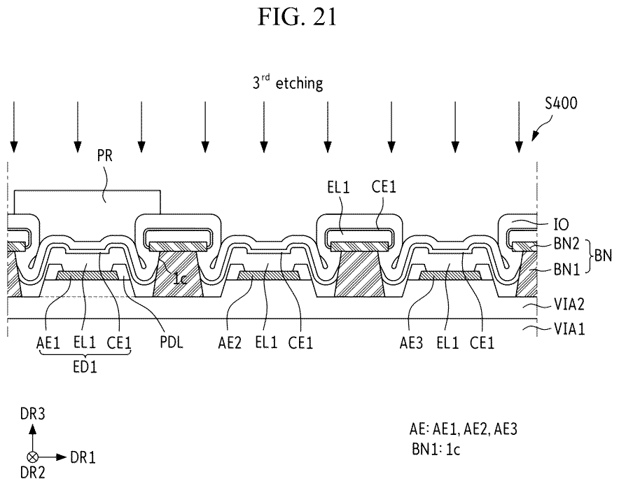

As illustrated in FIG. 21, a first cathode electrode CE1 and an element inorganic layer IO may be formed on the first light emitting layer EL1.

In the process, the process of forming the first cathode electrode CE1 may be performed through a thermal deposition process or a sputtering process without using a separate fine metal mask. The process of forming the first cathode electrode CE1 may have a higher step coverage than the process of forming the first light emitting layer EL1.

In an embodiment, the process of forming the first cathode electrode CE1 may be performed while being inclined at a second angle from the upper surface of the anode electrode AE. The second angle described above may be a deposition incidence angle. For example, the second angle may be less than or equal to about 30 degrees. Accordingly, the material forming the first cathode electrode CE1 may be formed on the second anode electrode AE2, the third anode electrode AE3, and the bank structure BN in addition to the first anode electrode AE1. The material forming the first cathode electrode CE1 may be formed on a side surface of the first bank layer BN1 in addition to the upper surface of the anode electrode AE and the bank structure BN.

Accordingly, the first cathode electrode CE1 may entirely cover the first light emitting layer EL1, and the first cathode electrode CE1 may be in stable contact with the side surface 1c of the first bank layer BN1.

However, in the process, the material forming the first cathode electrode CE1 formed on the first anode electrode AE1, the second anode electrode AE2, the third anode electrode AE3, and the bank structure BN may be spaced apart from each other without being connected to each other, as the second bank layer BN2 includes the tip.

In the process, the material forming the first cathode electrode CE1 positioned in a portion overlapping the anode electrode AE may be formed with a uniform thickness. The thickness of the first cathode electrode CE1 positioned in the tip of the second bank layer BN2 and the periphery of the tip of the second bank layer BN2 may be less than the thickness of the first cathode electrode CE1 positioned in the portion overlapping the anode electrode AE.

However, the disclosure is not limited thereto, and as the process of forming the first cathode electrode CE1 is performed as a process having high step coverage characteristics, the material forming the first cathode electrode CE1 may be uniformly formed throughout.

An element inorganic layer IO may be formed on the first cathode electrode CE1. In the process, the element inorganic layer IO may be formed by a chemical evaporation deposition (CVD) process. The element inorganic layer IO may have high step coverage characteristics and may be formed with a uniform thickness along the profile of the substructure.

In the process, the element inorganic layer IO may entirely cover the anode electrode AE and the bank structure BN.

A photoresist PR may be formed on the element inorganic layer IO, and a third etching process may be performed using the photoresist PR as a mask. The photoresist PR may be formed to cover the first anode electrode AE1 and the bank structure BN positioned in the periphery of the first anode electrode AE1.

In the process, the first light emitting layer EL1 that does not overlap the photoresist PR, the material forming the first cathode electrode CE1, and the material forming the element inorganic layer IO in the third direction DR3 may be removed all at once.

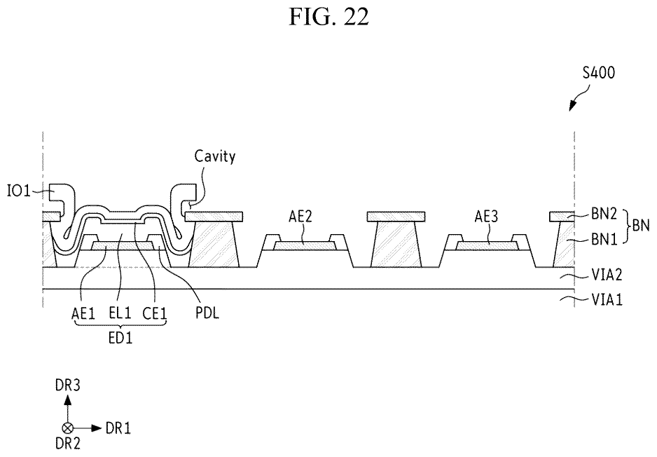

As illustrated in FIG. 22, through the process, the second anode electrode AE2 and the third anode electrode AE3 may be exposed again, and the element inorganic layer IO may be formed in the form of a first element inorganic layer IO1. As a result, the first light emitting element ED1 and the first element inorganic layer IO1 illustrated in FIG. 8 may be formed.

In the process, a cavity may be formed between an end of the first element inorganic layer IO1 and the second bank layer BN2 in the third direction DR3. The cavity may be formed by removing the material forming the first light emitting layer EL1 and the material forming the first cathode electrode CE1 that were temporarily positioned on the second bank layer BN2.

By repeating a same process, a second light emitting layer EL2 and a second cathode electrode CE2 may be formed on the second anode electrode AE2, thereby forming a second light emitting element ED2 and a second element inorganic layer IO2. By repeating a same process again, a third light emitting layer EL3 and a third cathode electrode CE3 may be formed on the third anode electrode AE3, thereby forming a third light emitting element ED3 and a third element inorganic layer IO3. As a result, the display element layer EML illustrated in FIG. 8 may be formed. Redundant descriptions will be omitted.

As described above, by forming the second via layer VIA2 to include the protruding portion prt and forming the anode electrode AE on the protruding portion prt of the second via layer VIA2, the light emitting layer EL may be uniformly formed in the light emitting area EA within the range of 10% or less. Therefore, a shadow defect by uneven thickness of the light emitting layer may be solved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate including a light emitting area and a non-light emitting area;
a via layer including a first portion positioned on the light emitting area of the substrate and a second portion positioned on the non-light emitting area of the substrate;
a first light emitting element positioned on the first portion of the via layer and including an anode electrode, a light emitting layer, and a first cathode electrode; and
a bank structure positioned on the second portion of the via layer, wherein
the first portion of the via layer includes a protruding portion that protrudes further in a direction perpendicular to the substrate than the second portion,
the anode electrode is in contact with the protruding portion of the first portion, and
the light emitting layer and the first cathode electrode are in contact with the bank structure.

2. The display device of claim 1, wherein a thickness of the protruding portion of the via layer is in a range of about 42% to about 70% of a thickness of the bank structure.

3. The display device of claim 2, wherein the protruding portion of the via layer is spaced apart from the bank structure in a direction parallel to the substrate.

4. The display device of claim 1, further comprising:
a pixel defining layer positioned on the first portion of the via layer, covering an edge of the anode electrode, and defining an opening,
wherein the pixel defining layer is in contact with the protruding portion of the first portion.

5. The display device of claim 4, wherein the anode electrode and the pixel defining layer are spaced apart from the bank structure in a direction parallel to the substrate.

6. The display device of claim 5, wherein the light emitting layer is in entirely contact with and covers the pixel defining layer and the anode electrode.

7. The display device of claim 4, wherein a thickness of the light emitting layer overlapping the opening in the direction perpendicular to the substrate has a thickness uniformity less than or equal to about 10%.

8. The display device of claim 7, wherein in a portion overlapping the non-light emitting area in the direction perpendicular to the substrate, the light emitting layer is in contact with and covers the protruding portion of the first portion.

9. The display device of claim 1, wherein
the bank structure includes:
a first bank layer in contact with the second portion of the via layer; and
a second bank layer positioned on the first bank layer and including a tip that protrudes further toward the light emitting area than a side surface of the first bank layer, and
the side surface of the first bank layer and the tip of the second bank layer form an undercut.

10. The display device of claim 9, wherein the side surface of the first bank layer includes:
a first portion in contact with the light emitting layer; and
a second portion in contact with the first cathode electrode.

11. The display device of claim 9, wherein
the first bank layer includes a first surface in contact with the second portion of the via layer, and
the anode electrode is positioned higher than the first surface by a thickness of the protruding portion of the via layer in the direction perpendicular to the substrate.

12. The display device of claim 9, further comprising:
a second light emitting element spaced apart from the first light emitting element with the bank structure interposed between the first light emitting element and the second light emitting element, wherein
the second light emitting element includes a second cathode electrode,
the second cathode electrode is in contact with the first bank layer, and
the first cathode electrode and the second cathode electrode are electrically connected by the first bank layer.

13. The display device of claim 12, further comprising:
a first element inorganic layer positioned on the first light emitting element; and
a second element inorganic layer positioned on the second light emitting element,
wherein the first element inorganic layer and the second element inorganic layer are in contact with the first bank layer.

14. The display device of claim 13, wherein an end of the first element inorganic layer and an end of the second element inorganic layer are spaced apart from the second bank layer by a cavity interposed between the second bank and the end of the first element inorganic layer and the end of the second element inorganic layer in the direction perpendicular to the substrate.

15. The display device of claim 13, wherein in a portion overlapping the non-light emitting area in the direction perpendicular to the substrate, the first element inorganic layer and the second element inorganic layer are spaced apart from each other in a direction parallel to the substrate.

16. A method for fabrication of a display device, the method comprising:
forming an anode electrode on a substrate including a via layer;
forming a pixel defining layer on the anode electrode;
forming a protruding portion of the via layer by removing a portion of the pixel defining layer and the via layer;
forming a bank structure in a portion that does not overlap the protruding portion of the via layer in a direction perpendicular to the substrate; and
forming a light emitting layer and a cathode electrode on the anode electrode to overlap the protruding portion of the via layer in the direction perpendicular to the substrate.

17. The method of claim 16, wherein in the forming of the protruding portion of the via layer by removing the portion of the pixel defining layer and the via layer,
the portion of the pixel defining layer and the via layer are simultaneously removed by a dry etching process.

18. The method of claim 16, wherein in the forming of the bank structure in the portion that does not overlap the protruding portion of the via layer,
the bank structure includes a first bank layer and a second bank layer including different materials,
an electrical conductivity of the first bank layer is higher than an electrical conductivity of the second bank layer, and
an etching resistance of the second bank layer is higher than an etching resistance of the first bank layer.

19. The method of claim 16, wherein in the forming of the light emitting layer and the cathode electrode on the anode electrode to overlap the protruding portion of the via layer,
the light emitting layer and the cathode electrode are formed by a deposition process and a photo pattern process without a separate fine metal mask.

20. An electronic device comprising:
at least one display device including a substrate including a light emitting area and a non-light emitting area;
a display device accommodating portion in which the at least one display device is accommodated; and
an optical member enlarging a display image of the at least one display device or converting a light path, wherein
the at least one display device includes:
a via layer including a first portion positioned on the light emitting area of the substrate and a second portion positioned on the non-light emitting area of the substrate;
a light emitting element positioned on the first portion of the via layer and including an anode electrode, a light emitting layer, and a cathode electrode; and
a bank structure positioned on the second portion of the via layer,
the first portion of the via layer includes a protruding portion that protrudes further in a direction perpendicular to the substrate than the second portion,
the anode electrode is in contact with the protruding portion of the first portion, and
the light emitting layer and the cathode electrode are in contact with the bank structure.
